(19) United States
(12) Patent Application Publication
(10) Pub. No.: US 2009/0292485 A1
(43) Pub. Date: Nov. 26, 2009

(54) System and Method for Synchronized Measurements

(76) Inventors: John C. Van Gorp, Sidney (CA); Jon A. Bickel, Murfreesboro, TN (US); Peter Cowan, Victoria (CA); Hubert Lindsay, Sooke (CA)

Correspondence Address: SCHNEIDER ELECTRIC / SQUARE D COMPANY;LEGAL DEPT. - I.P. GROUP (NP), 1415 S. ROSELLE ROAD, PALATINE, IL, 60067, US

(21) Appl. No.: 12/126,606

(22) Filed: May 23, 2008

(51) Int. Cl. G01R 29/00

(52) U.S. Cl. 702/57

(57) ABSTRACT

A system and method of synchronizing measurements between a master monitor (130 and/or 132) and a slave monitor (154 and/or 164). A system controller (110) receives master samples representing a signal characteristic from the master monitor (130 and/or 132) and slave samples representing the signal characteristic from the slave monitor (154 and/or 164). The master samples and slave samples are aligned using correlation analysis to obtain the identification of a slave sample that aligns with a predetermined master sample. This identification is transmitted to the slave monitor and used to synchronize a master measurement with a slave measurement.

### FIELD OF THE INVENTION

This invention relates to power monitoring, including but not limited to synchronizing measurements between power monitors.

### BACKGROUND OF THE INVENTION

Power monitoring system applications exist that benefit from the synchronization of a common measurement between monitors in a power monitoring system. One established method for synchronizing measurement intervals between monitors utilizes a synchronizing pulse from a master monitor to a slave monitor to indicate transitions between measurement intervals. Such a pulse may be transmitted between monitors using a cable when the monitors are in close proximity to each other, but this approach becomes prohibitively expensive when monitors are physically distant from one another. An approach for transmitting a synchronizing pulse over long distances makes use of additional equipment such as wireless relays that receive a pulse from a master monitor at one location and recreate the pulse for a slave monitor at another location, adding cost and additional components to the deployment and operation of a monitoring system.

### SUMMARY OF THE INVENTION

A plurality of master samples representing a signal characteristic is received from a master monitor. A first plurality of slave samples representing the signal characteristic is received from a first slave monitor. The plurality of master samples and first plurality of slave samples are aligned using correlation analysis, yielding a first identification of one of the first plurality of slave samples that aligns with a predetermined master sample of the plurality of master samples. The first identification is transmitted to the first slave monitor, and a first slave measurement is synchronized with a first master measurement using the first identification.

### BRIEF DESCRIPTION OF THE DRAWINGS

FIG. 1 is a block diagram of a system including a system controller, master monitors, and slave monitors in accordance with the invention.

FIG. 2 is a flowchart showing a method of synchronizing master measurement and slave measurement in accordance with the invention.

FIG. 3 is a diagram showing master and slave samples correlating to a value of a signal characteristic in accordance with the invention.

FIG. 4 is a diagram showing correlated master and slave samples in accordance with the invention.

FIG. 5 is a diagram showing measurement intervals and measurement sub-intervals correlating to cycle counter values in accordance with the invention.

### DETAILED DESCRIPTION

The following describes a system and method of synchronizing measurements between a master monitor and a slave monitor. Data samples representing a signal characteristic are received from the master monitor and slave monitor and aligned using correlation analysis. A slave sample that aligns with a predetermined master sample is identified, and this identification is transmitted to the slave monitor. This identification is used by the slave monitor to align a slave measurement with a corresponding master measurement. The words “master” and “slave” in the present specification and claims are arbitrarily selected labels that identify the monitors. Although the monitor identified as a “master monitor” may operate in the fashion expected of a master device, for the purposes of the present specification and claims, the “slave monitor” may operate as a master device and the “master monitor” may operate as a slave device. Thus, the identification may be used by the master monitor to align a master measurement with a corresponding slave measurement.

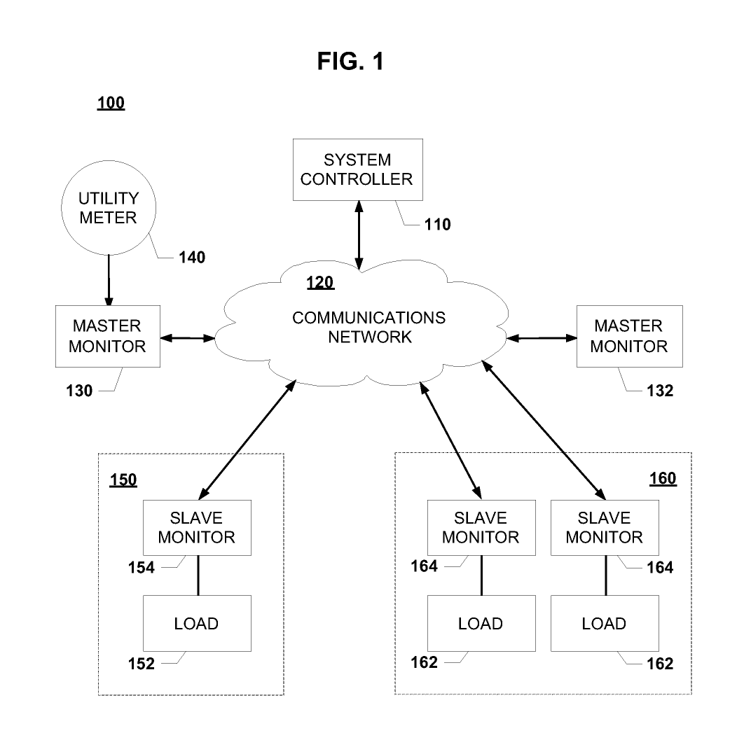

A block diagram of a system 100 including a system controller, master monitors, and slave monitors is shown in FIG. 1. The system 100 includes a system controller 110 that may be part of a server, personal computer, monitor, or other computing device, or multiple such devices alone or in combination. The system 100 also includes at least one master monitor 130 and 132, at least one slave monitor 154 and 164, and at least one load 152 and 162. The master monitors 130 and 132 and slave monitors 154 and 164 measure at least one parameter for the loads 152 and 162. The loads 152 and 162 may be equipment or processes such as electric motors, lights, and heating, ventilation and air conditioning (HVAC) units, as well as piped loads attached to water, gas, air, and steam distribution systems. The system controller 110 manages operation of the monitoring system, performing tasks such as acquiring data from and issuing commands to the monitors 130, 132, 154, and 164. The system controller 110 may also store and process data received from the monitors 130, 132, 154, and 164 and present information to a user (not shown).

The master monitors 130 and 132 and slave monitors 154 and 164 communicate with the system controller 110 via a communications network 120. The communication network 120 may include public and/or private communication channels/networks, one or more serial communications loops and/or buses, the internet, an intranet, an extranet and/or any other network configuration, and the communication network 120 may utilize wireline and/or wireless (not shown) communication media. Alternately, the system controller 110 may be directly coupled (not shown) to or part of the master monitors 130 and 132 and/or slave monitors 154 and 164.

Each monitor 130, 132, 154, or 164 is a device capable of measuring at least one parameter of a load. By way of example, a monitor 130, 132, 154, or 164 connected to a load 152 or 162 may measure electrical parameters such as voltage, current, frequency, and power demand. The monitors 130, 132, 154, and 164 may be capable of storing values for such parameters. A monitor 130, 132, 154, or 164 may also be capable of acquiring information from other devices using digital communications and/or digital/analog input/output (I/O) signalling. Examples of monitor types include power meters, trip units, relays, and motor control units. One example of a monitor is the ION® 7650 Intelligent Metering and Control Device sold by Schneider Electric, Saanichton/Victoria, British Columbia, Canada.

It is not uncommon for signals derived from measurements at various points in an energy distribution system to substantially simultaneously exhibit variations, i.e., deviations, in a signal characteristic, such as variations in amplitude and frequency. For example, variations in a parameter, such as frequency, tend to occur substantially simultaneously at different points in an electrical distribution system. The simultaneous nature of such variations may be used to synchronize different measurements performed by monitors. As an example, power system frequency variations measured by monitors connected at different points in an electrical distribution system may be used to synchronize the power demand measurements performed by the monitors, as described in more detail below.

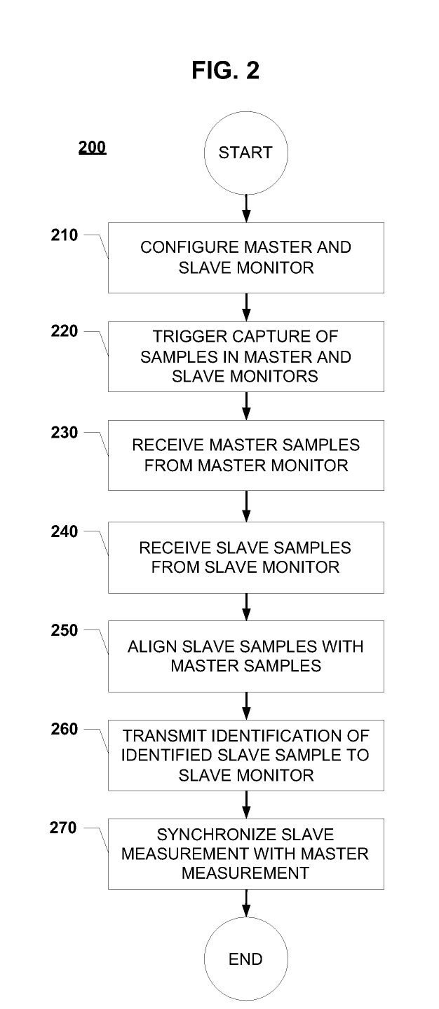

A method of synchronizing measurements between a master monitor and at least one slave monitor is described by the flowchart 200 shown in FIG. 2. This method is advantageously performed by the system controller 110. This method may optionally be performed by the master monitor 130 and 132 and/or the slave monitor 154 and 164. At step 210, the master monitor 130 and 132 and slave monitor 154 and 164 are configured to monitor variations in a signal characteristic. A cycle counter is used to count each cycle of the monitored signal. Other methods of counting cycles of the monitored signal may be utilized, as known in the art. Such configuration tasks may be initiated by a program running on the monitors 130, 132, 154, and 164, or may be initiated by an instruction from the system controller 110.

In step 220, sample data representing variations in the signal characteristic is captured by the monitors 130, 132, 154, and 164 in response to a command. The command may be generated by a program running on the monitors 130, 132, 154, and 164. The command may be received from the system controller 110 and issued at regular time intervals and/or when the system controller 110 detects that a monitor 130, 132, 154, or 164 has experienced a reset operation.

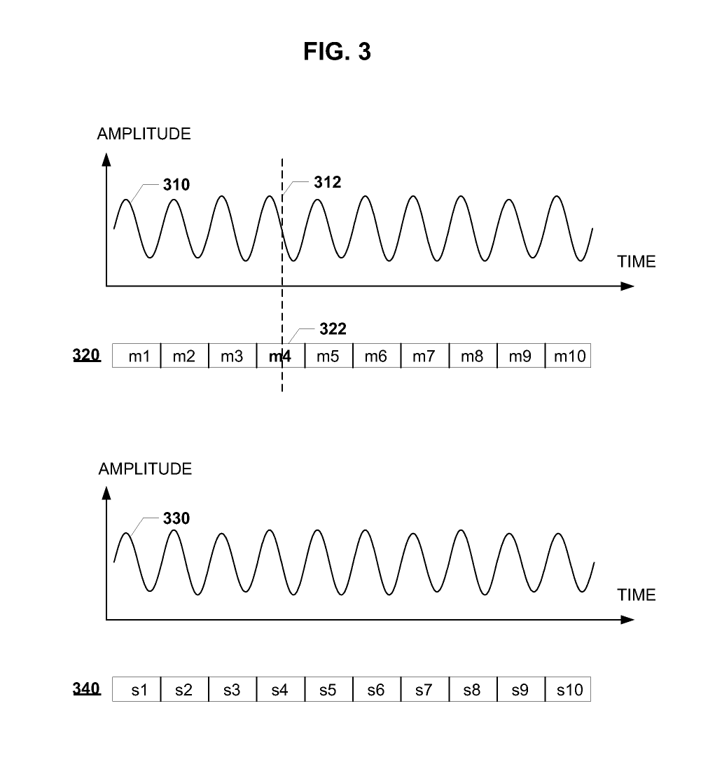

A diagram showing master and slave samples correlating to a signal characteristic is shown in FIG. 3. The master monitors 130 and 132 and the slave monitors 154 and 164 are configured to measure a signal characteristic at regular intervals and store this information for further processing. As an example, a master signal 310 may represent voltage as measured by the master monitor 130 and a slave signal 330 may represent voltage as measured by the slave monitor 154. The signal characteristic may be variations or deviations in frequency of the signals 310 and 330 away from the expected frequency. In this example, the master monitor 130 is configured to monitor the master signal 310 every cycle for variations from the expected frequency and stores these measured variations ml through m14 in a master sample stream 320. In a similar fashion, the slave monitor 154 monitors the slave signal 330 and stores measured variations s1 through s14 into a slave sample stream 340. An identification is generated for each sample in the master sample stream 320 that incorporates the cycle counter value for a cycle of the master signal 310 that aligns with each sample in master sample stream 320. In a similar fashion, an identification is generated for each sample in the slave sample stream 340 that incorporates the cycle counter value for a cycle of the slave signal 330 that aligns with each sample in slave sample stream 340. Other methods for identifying samples may be utilized, as long as the samples are uniquely identified. For example, an identification may incorporate the combination of a unique identifier for a monitor (such as a serial number) with a cycle counter value. An identification may also incorporate a pseudorandom seed generator to generate an initial ID value.

For purposes of identification, a trigger advantageously occurs at time 312 during the predetermined master sample 322. As an example, the trigger may be a signal generated at regular and/or random time intervals by the master monitor 130, and/or generated by pre-configured events such as setpoint or alarm conditions. The trigger may also be based on a signal received by the master monitor 130. By way of example, a utility meter 140 shown in FIG. 1 may provide an end-of-interval (EOI) pulse to the master monitor 130 to signal the transition from one power demand interval to the next, and the master monitor 130 may use this received EOI pulse as the trigger.

At steps 230 and 240 shown in FIG. 2, master samples from the master monitor 130 and 132, and slave samples from the slave monitor 154 and 164, are received by the system controller 110.

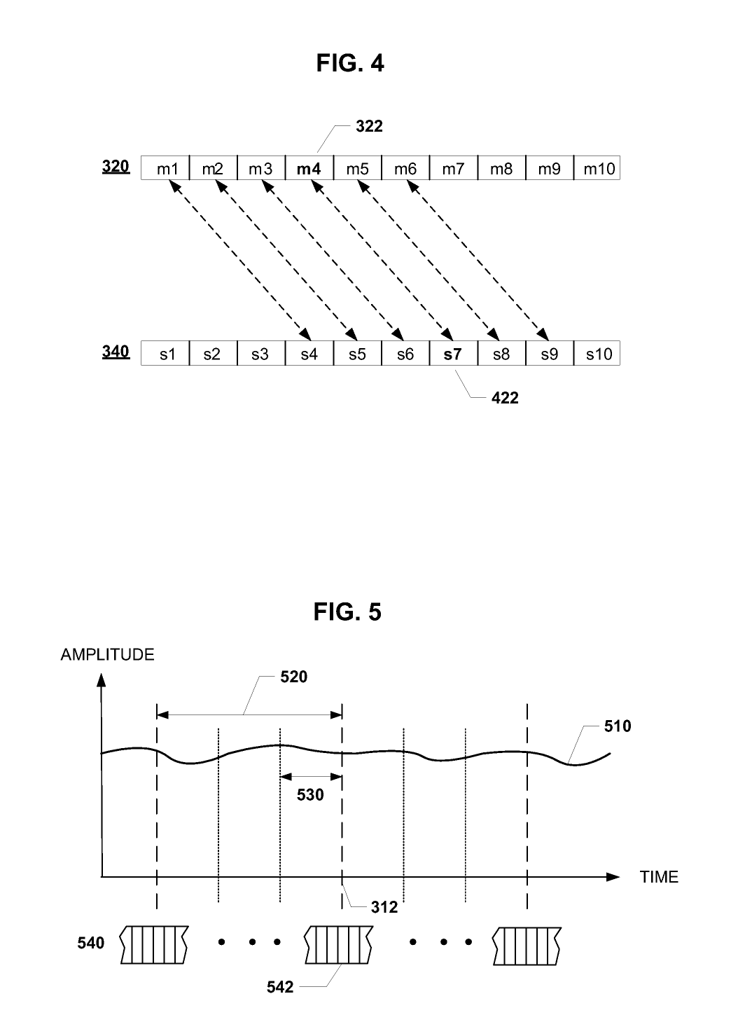

At step 250 shown in FIG. 2, the system controller 110 aligns the master samples with the slave samples. A diagram showing correlated master samples and slave samples is shown in FIG. 4. Various methods of finding the strongest correlation between samples may be used, as described in more detail below.

As an example, the following approach aligns the samples from the master sample stream 320 with the samples from the slave sample stream 340. In this example, 14 samples comprise the sample set. The values m1 through m14 in the master sample stream 320 are compared directly with the values s1 through s14 in the slave sample stream 340 using a correlation algorithm, yielding a first-pass correlation coefficient. The correlation algorithm may be one of a number of known algorithms, including linear regression, non-linear regression, polynomial regression, and any other applicable correlation algorithm to determine a correlation between two or more sets of values. An equation for one method of calculating a correlation coefficient is shown below.

$$r ( d ) = \frac{{\sum }_{i} [ ( x ( i ) - mx ) * ( y ( i - d ) - my ) ]}{\sqrt{{\sum }_{i} {( x ( i ) - mx )}^{2}} \sqrt{{\sum }_{i} {( y ( i - d ) - my )}^{2}}}$$

where r(d) is the correlation coefficient; d represents the delay (offset or shift in samples); −1≦r(d)≦1; x(i) and y(i) represent the sample data from the master and slave monitors 130, 132, 154, and 164; and mx and my are the means of the corresponding series x(i) and y(i). The correlation algorithm may be a circular correlation algorithm in which out-of-range indices are “wrapped” back within range. Alternatively, the correlation algorithm may be a linear correlation algorithm in which each series is repeated. The correlation algorithm may optionally be a pattern-matching algorithm or a text-search algorithm.

The slave samples in the slave sample stream 340 are shifted relative to the master samples in the master sample stream 320 such that m1 is compared with s2, m2 is compared with s3, and so on, up to and including comparing m14 with s1, and yielding a second-pass correlation coefficient. This process is repeated until each master sample has been compared with each slave sample in the sample set. Sample alignment methods are described in detail in U.S. Patent Publication US20070014313 titled “Automated Precision Alignment of Data in a Utility Monitoring System” having inventors Jon A. Bickel et al. Sample alignment methods are also described in detail in U.S. Patent Publication US20080065712 titled “Automated data alignment based upon indirect device relationships” having inventors Jon A. Bickel et al.

The correlation coefficients from each pass are compared with each other, and the correlation coefficient value that indicates the strongest correlation indicates alignment between the master samples and slave samples. If the strongest correlation is indicated by correlation coefficients of multiple passes, the system controller 110 may acquire new samples from the monitors 130, 132, 154, and 161 and repeat the alignment process described previously. In the example alignment illustrated in FIG. 4, the shift in slave samples from a comparison of m1 with s4 (and m2 with s5, and so on) resulted in the strongest correlation between samples of the master sample stream 320 and samples of the slave sample stream 340. This strongest correlation leads to an identification of a slave sample 422 as the sample that aligns with the predetermined master sample 322.

At step 260 shown in FIG. 2, the system controller 110 transmits the identity of the identified slave sample 422 to the slave monitor 154. The system controller 110 may transmit this identification immediately after the alignment of step 250 is complete or may transmit this identification when the master samples and slave samples are no longer aligned by N samples, where N is an integer.

At step 270 shown in FIG. 2, the slave monitor 154 uses the slave sample identification received from the system controller 110 to synchronize a slave measurement with a master measurement. By way of example, measurements that may be synchronized using the method described above include power demand, interval energy consumption, and averages of measurements such as voltage and current.

A diagram showing measurement intervals and measurement sub-intervals correlating to cycle counter values is shown in FIG. 5. Each measurement interval 520 is shown between dashed lines and is comprised of multiple sub-intervals 530. It is common for some measurements, such as kW demand, to be determined by operating on values gathered over multiple sub-intervals. By way of example, signal 510 may represent kW values, measurement interval 520 may represent a demand interval of 15 minutes and measurement sub-intervals 530 may represent demand sub-intervals of 5 minutes. If a sliding-window demand calculation method is utilized, the kW values within each 5-minute demand sub-interval are averaged, and three of these 5-minute averages are themselves averaged to determine the kW demand for the 15-minute demand interval. A variety of sliding-window demand interval configurations are commonly used, including demand intervals comprised of a single sub-interval.

The slave sample identification 422 received by slave monitor 154 may be used to synchronize a slave measurement with a master measurement at time 312. The slave monitor 154 stores values of signal 510, noting which cycle counter value in a cycle counter stream 540 aligns with each value. The slave sample identification 422 is matched with an associated cycle counter value 542, which aligns with time 312. Continuing the example above, the time 312 may represent the transition from one kW demand interval to the next as may be determined by the master monitor 130. The slave monitor 154 has the same sliding-window demand interval configuration as the master monitor 130. Noting that the stored kW value corresponding to cycle counter value 542 is at the transition between kW demand intervals as may be determined by the master monitor 130, the slave monitor 154 retrieves the stored kW values required to determine a kW demand measurement that is synchronized with a kW demand measurement by the master monitor 130.

The slave monitor 154 may determine the slave measurement after a slave sample identification 422 is received from the system controller 110, yielding a slave measurement that is synchronized with the master measurement. If the time interval for master and slave measurements is substantially regular, the slave monitor 154 may use an internal timer to aggregate slave sub-measurement interval 530 values and calculate slave measurements until the slave monitor 154 receives a slave sample identification 422 from the system controller 110.

Steps 240 through 270 are repeated for each slave monitor associated with a master monitor in a measurement synchronization group. These groups illustrate a master-slave measurement synchronization relationship between a master monitor and its associated slave monitor(s). As an example, consider the measurement synchronization groups 150 and 160 shown in FIG. 1. The slave monitor 154 may be associated with the master monitor 130 to form the measurement synchronization group 150, and the slave monitors 164 may be associated with the master monitor 132 to form the measurement synchronization group 160.

The present invention provides the following advantages. A slave measurement may be synchronized with a master measurement using an existing monitoring communications network and without requiring additional or specialized hardware. Applying the present invention, master and slave measurements are capable of being synchronized within a single cycle of the power system, an improvement over monitoring systems that broadcast a synchronization signal to one or more slave monitors, and an improvement over monitoring systems requiring long cable runs to communicate end-of-interval pulses between monitors. By storing values, the slave monitor compensates for communication and system controller processing delays when synchronizing a slave measurement with a master measurement. Variations in a signal characteristic of one type of measurement can be used to align other types of measurements, e.g., variations in power system frequency can be used to synchronize kW demand, interval kWh, and average current.

The present invention may be embodied in other specific forms without departing from its spirit or essential characteristics. The described embodiments are to be considered in all respects only as illustrative and not restrictive. The scope of the invention is, therefore, indicated by the appended claims rather than by the foregoing description. All changes that come within the meaning and range of equivalency of the claims are to be embraced within their scope.

What is claimed is:

1. A method comprising the steps of:
receiving a plurality of master samples representing a signal characteristic from a master monitor;
receiving a first plurality of slave samples representing the signal characteristic from a first slave monitor;
aligning the plurality of master samples with the first plurality of slave samples using correlation analysis, yielding a first identification of one of the first plurality of slave samples that aligns with a predetermined master sample of the plurality of master samples;
transmitting the first identification to the first slave monitor;
synchronizing a measurement by the first slave monitor with a measurement by the master monitor using the first identification.

2. The method of claim 1, wherein the synchronizing step comprises triggering a transition between a first power demand interval and a second power demand interval on the first slave monitor.

3. The method of claim 2, further comprising calculating a power demand measurement to synchronize with a power demand measurement on the master monitor.

4. The method of claim 1, wherein a trigger occurs during the predetermined master sample.

5. The method of claim 1, wherein a trigger is received by the master monitor and occurs during the predetermined master sample.

6. The method of claim 1, wherein the signal characteristic is one or more of frequency variation, amplitude variation, or both.

7. The method of claim 1, wherein the step of aligning comprises shifting the first plurality of slave samples relative to the plurality of master samples until a correlation is selected.

8. The method of claim 1, further comprising the step of transmitting an instruction to at least one of the master monitor and first slave monitor to store a plurality of samples.

9. The method of claim 1, wherein the first identification is transmitted when the alignment between the first plurality of slave samples and plurality of master samples has deviated more than a predetermined amount.

10. The method of claim 1, wherein a first master monitor and at least the first slave monitor comprise a measurement synchronization group amongst which the monitors are synchronized.

11. The method of claim 1, further comprising the steps of:
receiving a second plurality of slave samples from a second slave monitor;
aligning the plurality of master samples and the second plurality of slave samples using correlation analysis, yielding a second identification of one of the second plurality of slave samples that aligns with a predetermined sample of the plurality of master samples;
transmitting the second identification to the second slave monitor;
synchronizing a measurement by the second slave monitor with the measurement by the master monitor using the second identification.

12. A monitoring system comprising:
a system controller that:
receives a plurality of master samples and a first plurality of slave samples;
aligns the plurality of master samples and the first plurality of slave samples using correlation analysis, yielding a first identification of one of the first plurality of slave samples that aligns with a predetermined master sample of the plurality of master samples;
transmits the first identification to a first slave monitor, synchronizing a measurement by the first slave monitor with a measurement by a master monitor;
the master monitor operably coupled with the system controller and adapted to generate the plurality of master samples representing a signal characteristic;
the first slave monitor operably coupled with the system controller and adapted to generate the first plurality of slave samples representing the signal characteristic.

13. The system of claim 12, wherein the synchronizing comprises triggering a transition between a first power demand interval and a second power demand interval on the first slave monitor.

14. The system of claim 13, further comprising calculating a power demand to synchronize with a power demand measurement on the master monitor.

15. The system of claim 12, wherein a trigger is received by the master monitor and occurs during the predetermined master sample.

16. The system of claim 12, wherein alignment by the system controller comprises shifting the first plurality of slave samples relative to the plurality of master samples until a correlation is selected.

17. The system of claim 12, further comprising the system controller transmitting an instruction to at least one of the master monitor and first slave monitor to store a plurality of samples.

18. The system of claim 12, wherein the first identification is transmitted when the alignment between the first plurality of slave samples and plurality of master samples has deviated more than a predetermined amount.

19. The system of claim 12, wherein the system controller is integrated within the master monitor.

20. A method comprising the steps of:
receiving a first plurality of samples representing a signal characteristic from a first monitor;
receiving a second plurality of samples representing the signal characteristic from a second monitor, wherein the first monitor and at least the second monitor comprise a measurement synchronization group amongst which the monitors are synchronized;
aligning the first plurality of samples with the second plurality of samples using correlation analysis, shifting the second plurality of samples relative to the first plurality of samples until a correlation is selected, yielding a first identification of one of the second plurality of samples that aligns with a predetermined sample of the first plurality of samples, wherein a trigger occurs during the predetermined sample;
transmitting the first identification to the second monitor when the alignment between the second plurality of samples and first plurality of samples has deviated more than a predetermined amount;
synchronizing a measurement by the second monitor with a measurement by the first monitor using the first identification, by triggering a transition between a first power demand interval and a second power demand interval on the second monitor;
transmitting an instruction to at least one of the first monitor and second monitor to store a plurality of samples.
